(19) United States
(12) Patent Application Publication
(10) Pub. No.: US 2026/0162736 A1
(43) Pub. Date: Jun. 11, 2026

(54) NONVOLATILE MEMORY DEVICES WITH LEAKAGE DETECTION

(71) Applicant: Samsung Electronics Co., Ltd., Suwon-si (KR)

(72) Inventors: Philkyu KANG, Suwon-si (KR); Yohan LEE, Suwon-si (KR); Doohyun KIM, Suwon-si (KR); Beomjin PARK, Suwon-si (KR); Kwangho CHOI, Suwon-si (KR)

(21) Appl. No.: 19/405,149

(22) Filed: Dec. 1, 2025

(30) Foreign Application Priority Data
Dec. 11, 2024 (KR) 10-2024-0184190

(51) Int. Cl. G11C 16/34; G11C 16/10; G11C 16/26

(52) U.S. Cl. CPC G11C 16/3418; G11C 16/102; G11C 16/26; G11C 16/3459

(57) ABSTRACT

A method of operating a memory device including a plurality of memory cells each connected to a respective one of a plurality of bitlines and a respective one of plurality of wordlines, includes: storing data for performing a program operation in at least one latch, among a plurality of latches included in each of a plurality of page buffers each connected to a respective one of the plurality of bitlines, detecting whether leakage occurs in a selected wordline among the plurality of wordlines while storing data in at least one of the plurality of latches, and outputting leakage information when it is determined that leakage has occurred in the selected wordline.

### CROSS-REFERENCE TO RELATED APPLICATION

This U.S. non-provisional application claims priority under 35 USC § 119 to Korean Patent Application No. 10-2024-0184190, filed on Dec. 11, 2024, in the Korean Intellectual Property Office, the entirety of which is herein incorporated by reference.

### BACKGROUND

Memory devices may be classified into volatile memory devices and nonvolatile memory devices, based on whether stored data is lost when power supply is interrupted. A memory device may include a flash memory device that is electrically erasable and programmable.

A memory device may include a memory cell array including a plurality of memory cells each connected to a respective one of plurality of wordlines and a respective one of a plurality of bitlines.

With the trend toward higher density in memory devices, leakage may occur in at least a portion of the plurality wordlines and bitlines. Such leakage may cause malfunctions during program, read, and erase operations of the memory device.

### SUMMARY

Some aspects of the present disclosure provide methods of detecting leakage of a memory device, e.g., before performing a program operation.

According to some implementations according to the present disclosure, there is provided a method of operating a memory device including a plurality of memory cells each connected to a respective one of a plurality of bitlines and a respective one of plurality of wordlines, the method including storing data for performing a program operation in at least one latch, among a plurality of latches included in each of a plurality of page buffers each connected to a respective one of the plurality of bitlines, detecting whether leakage occurs in a selected wordline among the plurality of wordlines while storing data in at least one of the plurality of latches, and outputting leakage information when it is determined that leakage has occurred in the selected wordline.

According to some implementations according to the present disclosure, there is provided a method of operating a memory device comprising a plurality of memory cells each connected to s respective one of a plurality of bitlines and a respective one of plurality of wordlines, the method including determining whether leakage occurs in a selected wordline, among the plurality of wordlines, while storing inhibit data in at least one of a plurality of latches included in each of a plurality of page buffers, outputting leakage information when it is determined that leakage has occurred in the selected wordline, and performing a program operation through the selected wordline when it is determined that no leakage has occurred in the selected wordline.

According to some implementations according to the present disclosure, a memory device includes a memory cell array including a plurality of memory cells connected to a plurality of wordlines and a plurality of bitlines, a page buffer circuit including a plurality of page buffers each connected to a respective one of the plurality of bitlines, and a control logic circuit connected to the memory cell array and the page buffer circuit. The control logic circuit may be configured to store inhibit data in each of the plurality of page buffers, detect whether leakage occurs in a selected wordline among the plurality of wordlines while storing the inhibit data in at least one of the plurality of page buffers, and output leakage information when it is determined that leakage has occurred in the selected wordline.

### BRIEF DESCRIPTION OF DRAWINGS

FIG. 1 is a block diagram of an example of a memory system.

FIG. 2 is a block diagram of an example of a memory device.

FIG. 3 is a diagram illustrating an example of detection of leakage between a string and a selected wordline using a page buffer.

FIG. 4 is a diagram illustrating an example of a configuration of a first page buffer.

FIG. 5 is a diagram illustrating an example of voltage change in a first bit line when leakage occurs between a first string and a selected wordline.

FIG. 6 is a block diagram of an example of a memory device including a leakage detection circuit.

FIG. 7 is a diagram illustrating an example of detection of leakage between a string and a selected wordline by applying a voltage to the selected wordline.

FIG. 8 is a diagram illustrating an example of voltage change in a selected wordline when leakage occurs between a first string and the selected wordline.

FIG. 9 is a diagram illustrating an example of detection of leakage between wordlines by applying different voltages to a selected wordline and an adjacent wordline.

FIG. 10 is a diagram illustrating voltage levels of a selected wordline and an adjacent wordline when leakage occurs between wordlines.

FIG. 11 is a flowchart illustrating an example of a method of operating a memory device.

FIG. 12 is a flowchart illustrating an example of a method of performing a program operation.

FIG. 13 is a flowchart illustrating an example of a method of detecting leakage between a first string and a selected wordline using a page buffer.

FIG. 14 is a flowchart illustrating an example of a method of detecting leakage between a first string and a selected wordline by applying a voltage to the selected wordline.

FIG. 15 is a flowchart illustrating an example of a method of detecting leakage between wordlines by applying different voltages to a selected wordline and an adjacent wordline.

FIG. 16 is a flowchart illustrating an example of a method of performing a verify operation after a program operation of a memory device.

### DETAILED DESCRIPTION

The term “first,” “second,” or the like used herein are used as labels regardless of the order and/or priority thereof, and are used only for distinguishing one element from another element, without requiring any order therebetween.

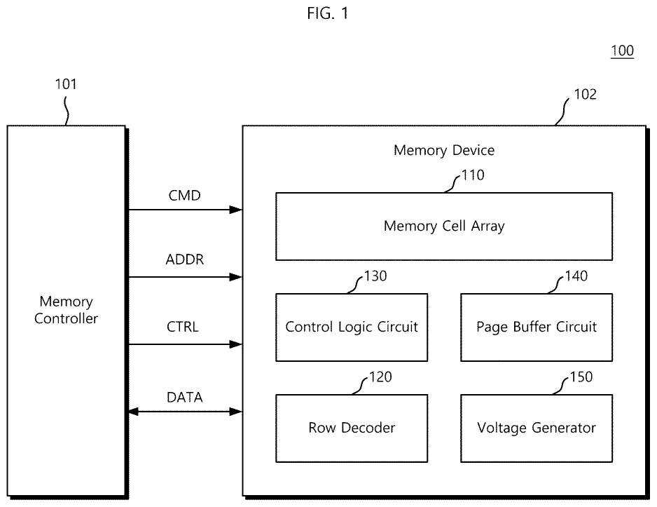

FIG. 1 is a block diagram of an example of a memory system. Referring to FIG. 1, a memory system 100 may include a memory controller 101 and a memory device 102. However, the configuration of the memory system 100 illustrated in FIG. 1 is an example, and other configurations may be provided in or for the memory system 100.

In some implementations, the memory system 100 may be an internal memory embedded in an electronic device. For example, the memory system 100 may be an embedded universal flash storage (UFS) memory device, an embedded multimedia card (eMMC), or a solid state drive (SSD).

In some implementations, the memory system 100 may be external memory, removable from an electronic device. For example, the memory system 100 may include at least one of a UFS memory card, a compact flash (CF) card, a secure digital (SD) card, a micro secure digital (Micro-SD) card, a mini secure digital (Mini-SD) card, a mini secure digital (mini SD) card, an extreme digital (xD) card, or a memory stick.

The memory system 100 may include a memory controller 101 controlling the operation of the memory device 102.

For example, the memory controller 101 may control the memory device 102 to write data in the memory device 102 in response to a write request from a host. In addition, the memory controller 101 may control the memory device 102 to read data stored in the memory device 102 in response to a read request from the host.

In addition, the memory system 100 may include a memory device 102 storing, reading, or erasing data under the control of a memory controller 101.

For example, the memory device 102 may receive at least one of commands CMD, addresses ADDR, and control signals CTRL from the memory controller 101. In addition, the memory device 102 may transmit and receive data DATA for a program operation or a read operation to and from the memory controller 101.

The memory device 102 may include a memory cell array 110, a row decoder 120, a control logic circuit 130, a page buffer circuit 140, and a voltage generator 150.

The memory cell array 110 may include a plurality of memory cells. For example, the memory cell array 110 may include a plurality of memory cells each connected to a respective one of a plurality of word lines and a respective one of a plurality of bit lines.

The row decoder 120 may select one of a plurality of wordlines connected to the memory cell array 110 in response to at least a portion of the addresses ADDR. In addition, the row decoder 120 may apply a voltage to the selected wordline.

The voltage generator 150 may generate a program voltage and a verify voltage. In addition, the voltage generator 150 may generate and transmit the program voltage and the verify voltage to the row decoder 120.

The page buffer circuit 140 may select at least one of the plurality of bitlines connected to the memory cell array 110 in response to at least a portion of the addresses ADDR. For example, the page buffer circuit 140 may include a plurality of page buffers connected to each of the plurality of bitlines.

The control logic circuit 130 may control the overall operation of the memory device 102.

The control logic circuit 130 may execute, for example, software (or program) to control at least one other component (for example, the row decoder 120) of the first chip 121 and the page buffer circuit 140, and may perform various data processing or computations. The control logic circuit 130 may include a central processing unit, a microprocessor, or the like, and may control the overall operation of the memory device 102. Therefore, it will be understood that the operations performed by the memory device 102 are performed under the control of the control logic circuit 130.

In some implementations, the control logic circuit 130 may control at least a portion of the row decoder 120, the page buffer circuit 140, and the voltage generator 150.

For example, the control logic circuit 130 may control a voltage level of the program voltage and/or the verify voltage generated by the voltage generator 150. In addition, the control logic circuit 130 may control the row decoder 120 to provide a voltage to at least one of the plurality of wordlines. In addition, the control logic circuit 130 may control the page buffer circuit 140 to provide a voltage to at least one of the plurality of bitlines.

In some implementations, the control logic circuit 130 may detect whether leakage has occurred in at least a portion of the plurality of wordlines.

For example, the control logic circuit 130 may detect whether leakage has occurred in a selected wordline, among the plurality of wordlines, before performing program operations on at least one memory cell.

For example, the control logic circuit 130 may detect whether leakage has occurred in the selected wordline, among the plurality of wordlines, before performing a program operation on at least one memory cell.

For example, the control logic circuit 130 may detect whether leakage has occurred between two adjacent wordlines, before performing a program operation on at least one memory cell.

The control logic circuit 130 may detect whether leakage has occurred in at least a portion of the plurality of wordlines while setting data for performing a program operation through the page buffer circuit 140, before performing the program operation.

Furthermore, the control logic circuit 130 may output leakage information when it is determined that leakage has occurred in at least a portion of the plurality of wordlines. For example, the control logic circuit 130 may output leakage information when it is determined that leakage has occurred between a single string and a selected wordline.

In addition, the control logic circuit 130 may perform a program operation when it is determined that no leakage has occurred in the selected wordline.

For example, the control logic circuit 130 may apply a program voltage through the selected wordline when it is determined that no leakage has occurred in the selected wordline.

Referring to the above-described configurations, the control logic circuit 130 may determine whether leakage has occurred in a wordline, before performing a program operation.

Thus, the memory system 100 (or the memory device 102) may reduce the number of times program operations are performed through wordlines on which leakage has occurred.

With the above-described configurations, the memory system 100 may improve the performance of program operations on the memory device 102.

In addition, referring to the above-described configurations, the control logic circuit 130 may determine whether leakage has occurred in a wordline while setting data for a program operation.

As a result, the memory system 100 (or the memory device 102) may significantly reduce an increase in time required for a program operation caused by an operation of detecting whether leakage has occurred.

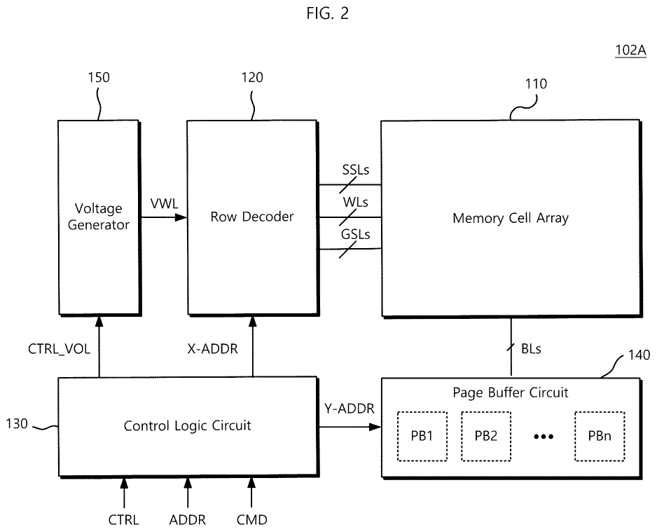

FIG. 2 is a block diagram of an example of a memory device.

Referring to FIG. 2, a memory device 102A may include a memory cell array 110, a row decoder 120, a control logic circuit 130, a page buffer circuit 140, and a voltage generator 150. However, the configuration of the memory device 102A is not limited to the configuration illustrated in FIG. 2, and the memory device 102A may further include other components (for example, an input/output interface).

In addition, the memory device 102A illustrated in FIG. 2 may be understood as an example of the memory device 102 illustrated in FIG. 1. Therefore, the same or substantially the same components are represented by the same reference numerals, and redundant descriptions will be omitted to avoid repetition.

In the memory device 102A, the memory cell array 110 may be connected to the row decoder 120 and the page buffer circuit 140.

The memory cell array 110 may be connected to the page buffer circuit 140 through a plurality of bitlines BLs. In addition, the memory cell array 110 may be connected to the decoder 120 through a plurality of wordlines WLs, string select lines SSLs, and ground select lines GSLs.

The memory cell array 110 may include a plurality of memory cells. For example, the memory cells may be flash memory cells. Alternatively, the memory cells may be resistive memory cells such as resistive RAM (ReRAM) memory cells, phase change RAM (PRAM) memory cells, or magnetic RAM (MRAM) memory cells. However, memory cells within the scope of this disclosure are not limited to the above examples.

For ease of description, the following examples will be described in detail by way of example in which a plurality of memory cells are NAND flash memory cells.

In some implementations, the memory cell array 110 may include a three-dimensional memory cell array. The three-dimensional memory cell array may include a plurality of NAND strings. Each of the NAND strings may memory cells each connected to a respective one of wordlines, vertically stacked on a substrate.

In some implementations, the memory cell array 110 may include a two-dimensional memory cell array. The two-dimensional memory cell array may include a plurality of NAND strings disposed in row and column directions.

The memory device 102A may include a row decoder 120 selecting one of a plurality of wordlines WLs.

For example, the row decoder 120 may select one of the plurality of wordlines WLs in response to a row address X-ADDR. In addition, the row decoder 120 may select one of a plurality of select lines SSLs in response to the row address X-ADDR.

In addition, the memory device 102A may include a page buffer circuit 140 connected to the memory cell array 110 through a plurality of bitlines BLs.

For example, the page buffer circuit 140 may select at least a portion of the plurality of bitlines BLs in response to a column address Y-ADDR.

In some implementations, the page buffer circuit 140 may operate as an input driver or a sense amplifier, depending on operation mode. For example, the page buffer circuit 140 may operate as an input driver during a program operation on the memory cell array 110. For example, the page buffer circuit 140 may operate as a sense amplifier during a read operation on the memory cell array 110.

For example, the page buffer circuit 140 may apply a bitline voltage corresponding to data to be programmed to at least a portion of the bitlines BLs of the memory cell array 110 during a program operation. The page buffer circuit 140 may sense data stored in a selected memory cell through a bitline during a read operation or a verify operation.

Each of the plurality of page buffers PB1 to PBn included in the page buffer circuit 140 may be connected to at least one bitline. In some implementations, the plurality of page buffers PB1 to PBn may be connected to the plurality of bitlines BLs, respectively. For example, the first page buffer PB1 may be connected to a first bitline.

In addition, the memory device 102A may include a voltage generator 150 generating a wordline voltage VWL.

For example, the voltage generator 150 may generate a wordline voltage VWL supplied to the memory cell array 110. The voltage generator 150 may generate different types of wordline voltages VWLs for performing program, read, and erase operations on the memory cell array 110 based on a voltage control signal CTRL_VOL.

For example, the voltage generator 150 may generate a program voltage, a read voltage, a pass voltage, and an erase voltage. For example, the voltage generator 150 may generate a verify voltage and an erase verify voltage. However, the types of voltages generated by the voltage generator 150 are not limited to the above-described examples.

In some implementations, the control logic circuit 130 may receive a control signal CTRL, a command CMD, and address ADDR from the memory controller 101. In addition, the control logic circuit 130 may transmit the row address X-ADDR to the row decoder 120 and the column address Y-ADDR to the page buffer circuit 140.

In addition, the control logic circuit 130 may transmit the voltage control signal CTRL_VOL to the voltage generator 150 based on at least a portion of the control signal CTRL, the command CMD, and the address ADDR.

For example, the control logic circuit 130 may transmit the voltage control signal CTRL_VOL to the voltage generator 150, instructing the generation of a program voltage for data programming, to perform a program operation.

In some implementations, the control logic circuit 130 may detect whether leakage has occurred in at least a portion of the plurality of wordlines WLs.

For example, the control logic circuit 130 may detect whether leakage has occurred in at least a portion of the plurality of wordlines WLs, before performing a program operation on the at least one memory cell.

In some implementations, the control logic circuit 130 may store data in at least a portion of latches included in each of the plurality of page buffers PB1 to PBn, before performing a program operation on the at least one memory cell.

For example, the control logic circuit 130 may store inhibit data in at least a portion of the latches included in each of the plurality of page buffers PB1 to PBn, before performing the program operation. The control logic circuit 130 may apply an inhibit voltage to a bitline, connected to a latch in which the inhibit data is stored, during a program operation.

In some implementations, the control logic circuit 130 may detect whether leakage occurs in at least a portion of the plurality of wordlines WLs while storing inhibit data in at least a portion of the plurality of latches.

For example, the control logic circuit 130 may detect whether leakage occurs between at least one of the strings, connected to each of the plurality of bitlines BLs, and a selected wordline while storing inhibit data in at least a portion of the plurality of latches.

For example, the control logic circuit 130 may detect whether leakage occurs between two adjacent wordlines while storing inhibit data in at least a portion of the plurality of latches.

For example, the control logic circuit 130 may detect whether leakage has occurred in a selected wordline while setting up data for performing a program operation through the page buffer circuit 140, before performing the program operation.

In some implementations, the control logic circuit 130 may output leakage information when it is determined that leakage has occurred in a selected wordline. For example, the control logic circuit 130 may output leakage information when it is determined that leakage has occurred between adjacent wordlines.

In some implementations, the control logic circuit 130 may perform a program operation when it is determined that no leakage has occurred in a selected wordline.

For example, the control logic circuit 130 may apply a program voltage through a selected wordline when it is determined that no leakage has occurred in the selected wordline.

For example, referring to the above-described configurations, the control logic circuit 130 may determine whether leakage has occurred in a selected wordline, before performing a program operation.

Thus, the memory device 102A may reduce the number of times program operations are performed through wordlines in which leakage has occurred.

With the above-described configurations and other configurations described herein, in some implementations, the memory device 102A may improve the performance of program operations on the memory cell array 110.

For example, in some implementations, the control logic circuit 130 may determine whether leakage has occurred in a selected wordline while setting data for a program operation.

As a result of the foregoing and other configurations and operations described herein, the memory device 102A may significantly reduce an increase in time required for a program operation caused by an operation of detecting whether leakage has occurred.

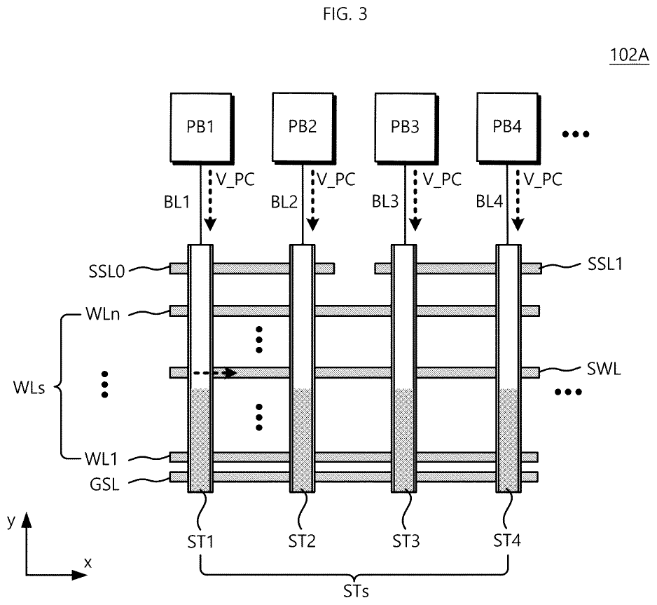

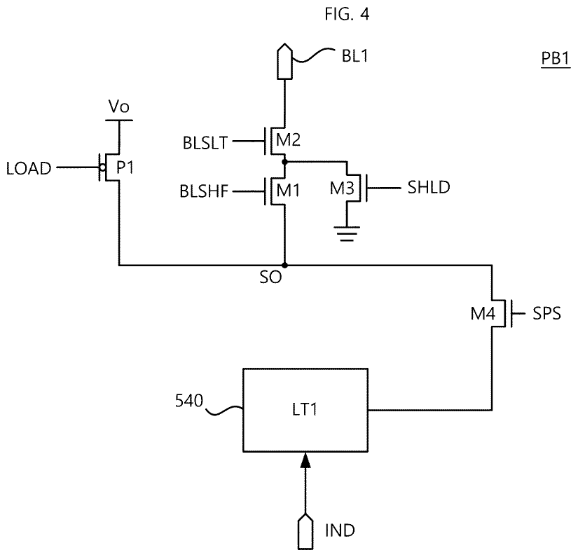

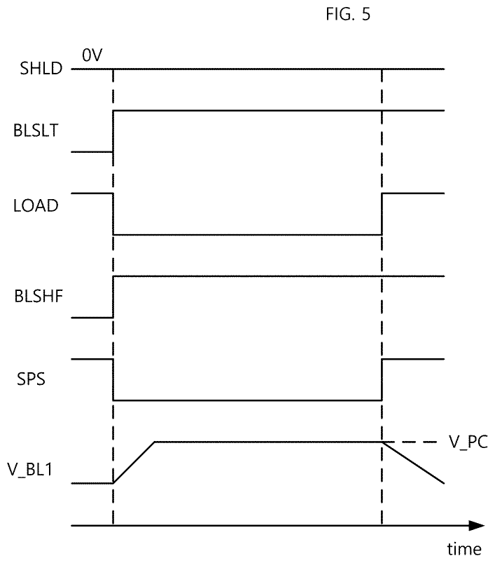

FIG. 3 is a diagram illustrating a configuration to detect leakage between a string and a selected wordline using a page buffer. FIG. 4 is a diagram illustrating a configuration of a first page buffer. FIG. 5 is a diagram illustrating a voltage change in a first bit line when leakage occurs between a first string and a selected wordline.

Referring to FIGS. 3 to 5, a memory device 102A or a control logic circuit 130 may detect leakage between a string (or a channel) and a selected wordline SWL using a plurality of page buffers PB1 to PB4.

For example, the control logic circuit 130 may apply a precharge voltage V_PC to the plurality of strings STs using the plurality of page buffers PB1 to PB4 to detect leakage between the plurality of strings STs and the selected wordline SWL.

In some implementations, the control logic circuit 130 may apply a precharge voltage V_PC to the plurality of strings STs using the plurality of page buffers PB1 to PB4 before performing a program operation.

Referring to FIG. 3, in some implementations, data is programmed in memory cells connected to wordlines disposed below the selected wordline SWL (for example, in a negative Y-direction). For example, in some implementations, when the selected wordline SWL is the fourth wordline, data has been pre-programmed in memory cells connected to wordlines WL1 to WL3.

Accordingly, in some implementations, program operations on the memory device 102A of FIG. 3 are performed in a sequence starting from the first wordline WL1 to the nth wordline WLn. However, the order of the program operations on the memory device 102A is not limited thereto.

The control logic circuit 130 may apply the precharge voltage V_PC to the plurality of strings STs through the plurality of page buffers PB1 to PB4, in a direction (for example, the negative Y-direction) from string select lines SSL0 and SSL1 toward a ground select line GSL.

Accordingly, in each of the plurality of strings STs, the precharge voltage V_PC may be charged to the memory cells connected to the selected wordline SWL to the nth wordline WLn.

Referring to FIG. 4, the first page buffer PB1 may include a plurality of transistors P1, M1, M2, M3, and M4 and a first latch LT1 (540).

The first page buffer PB1 may include a PMOS transistor P1 connected between an external voltage Vo and a sense node SO. The PMOS transistor P1 may be turned on or turned off in response to a load signal LOAD.

In addition, the first page buffer PB1 may include a first transistor M1 to a fourth transistor M4.

The first transistor M1 may be turned on or off in response to a bitline voltage control signal BLSHF. The second transistor M2 may be turned on or off in response to a bitline select signal BLSLT. The third transistor M3 may be turned on or off in response to a shield signal SHLD. The fourth transistor M4 may be turned on or off in response to a separation signal SPS.

Referring to FIGS. 4 and 5, the PMOS transistor P1 may be turned on by a low-level load signal LOAD. The first transistor M1 and the second transistor M2 may be turned on in response to a high-level bitline voltage control signal BLSHF and a high-level bitline select signal BLSLT.

Accordingly, the control logic circuit 130 may apply a voltage based on the external voltage Vo to the first bitline BL1 through the first page buffer PB1. The voltage based on the external voltage Vo may be understood as the precharge voltage V_PC of FIG. 3.

In some implementations, the control logic circuit 130 may store inhibit data IND in the first latch LT1 while applying the voltage based on the external voltage Vo to the first bitline BL1.

The fourth transistor M4 may be turned off in response to a low-level separation signal SPS while storing the inhibit data IND in the first latch LT1. As the fourth transistor M4 is turned off in response to the low-level disconnect signal SPS, the first latch LT1 may be electrically isolated from the first sensing node SO1.

For example, the control logic circuit 130 may store the inhibit data IND in the first latch LT1 while the first latch LT1 and the first sensing node SO1 are electrically isolated from each other. In addition, the control logic circuit 130 may apply a precharge voltage V_PC based on the external voltage Vo to the first bitline BL1 while storing the inhibit data IND in the first latch LT1.

Referring to the above-described configurations, the control logic circuit 130 may apply the precharge voltage V_PC to the first bitline BL1 using an external voltage Vo while storing the inhibit data IND in the first latch LT1.

In addition, the control logic circuit 130 may detect a voltage level V_BL1 of the first bitline BL1.

For example, the control logic circuit 130 may detect a voltage level V_BL1 of the first bitline BL1 after the PMOS transistor P1 is turned off by a high-level load signal LOAD to electrically isolate the first sense node SO1 from the external voltage Vo.

For example, the control logic circuit 130 may detect a voltage level V_BL1 on the first bitline BL1 using the first page buffer PB1 (or the first latch LT1). For example, the control logic circuit 130 may detect the voltage of the sense node SO using the first latch LT1 to detect the voltage level V_BL1 of the first bitline BL1. For example, the fourth transistor M4 may be set to an ON state when the isolation signal SPS is high.

In some implementations, when the voltage level V_BL1 of the first bitline BL1 is lower than the voltage level of the precharge voltage V_PC, the control logic circuit 130 may determine that leakage between the first string ST1 and the selected wordline SWL has occurred.

For example, when the voltage level V_BL1 on the first bitline BL1 is lower than the voltage level of the precharge voltage V_PC, the control logic circuit 130 may determine that leakage has occurred from the first string ST1 to the selected wordline SWL, as indicated by a dashed arrow in FIG. 3.

When it is determined that leakage between the first string ST1 and the selected wordline SWL has occurred, the control logic circuit 130 may output leakage information.

In some implementations, when the voltage level V_BL1 of the first bitline BL1 is equal to the voltage level of the precharge voltage V_PC, the control logic circuit 130 may determine that no leakage between the first string ST1 and the selected wordline SWL has occurred.

When it is determined that no leakage between the plurality of strings STs and the selected wordline SWL has occurred, the control logic circuit 130 may perform a program operation through the selected wordline SWL.

Referring to the above-described configurations, the control logic circuit 130 may determine leakage between the plurality of strings STs and the selected wordlines SWLs using the plurality of page buffers PB1 to PB4 while setting data for a program operation.

For example, the control logic circuit 130 may determine whether leakage occurs between the plurality of strings STs and the select wordlines SWLs using the plurality of page buffers PB1 through PB4 while storing the inhibit data IND in at least one of the plurality of latches.

For example, the control logic circuit 130 may determine whether leakage has occurred on the selected wordline SWL before performing the program operation.

Thus, the memory device 102A may reduce the number of times program operations are performed through wordlines in which leakage has occurred. With the above-described configurations, the memory device 102A may improve the performance of program operations on the memory cell array 110.

In addition, referring to the above-described configurations, the control logic circuit 130 may determine whether leakage has occurred on the selected wordline SWL while setting data for a program operation.

As a result, the memory device 102A may significantly reduce an increase in time required for a program operation caused by an operation of detecting whether leakage has occurred.

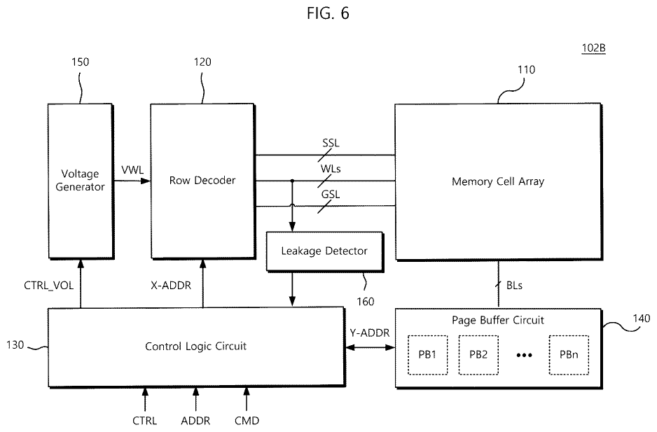

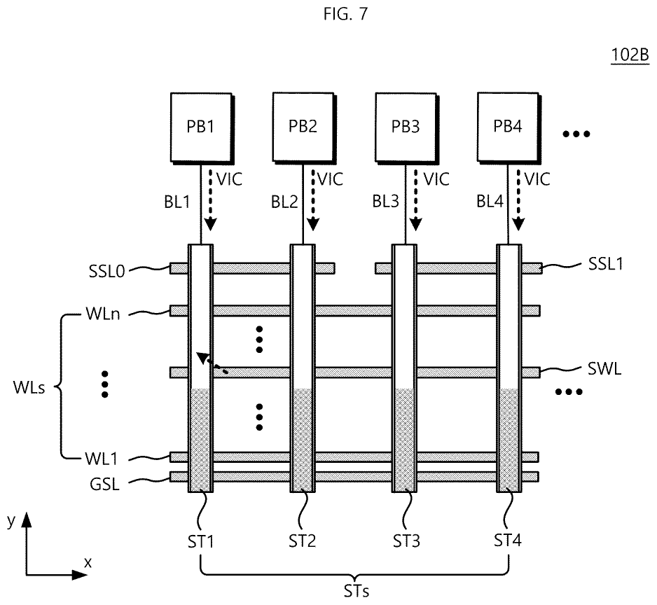

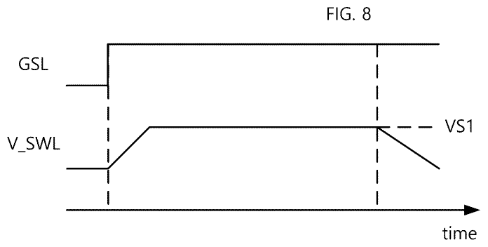

FIG. 6 is a block diagram of an example of a memory device including a leakage detection circuit. FIG. 7 is a diagram illustrating a configuration to detect leakage between a string and a selected wordline by applying a voltage to the selected wordline. FIG. 8 is a diagram illustrating a voltage change in a selected wordline when leakage occurs between a first string and the selected wordline.

Referring to FIG. 6, a memory device 102B may include a memory cell array 110, a row decoder 120, a control logic circuit 130, a page buffer circuit 140, a voltage generator 150, and a leakage detection circuit 160. However, the structure of the memory device 102B is not limited to the configuration illustrated in FIG. 6, and may further include other elements (for example, an input/output interface).

The memory device 102B illustrated in FIG. 6 may be understood as an example of the memory device 102 illustrated in FIG. 1. Therefore, the same or substantially similar components are represented by the same reference numerals, and redundant descriptions will be omitted to avoid repetition.

The memory device 102B may include a leakage detection circuit 160 connected between the plurality of wordlines WLs and the control logic circuit 130.

In some implementations, the leakage detection circuit 160 may be connected to each of the plurality of wordlines WLs.

The leakage detection circuit 160 may detect a voltage level of each of the plurality of wordlines WLs.

For example, the leakage detection circuit 160 may include a reference voltage generator and a comparator. The leakage detection circuit 160 may compare a reference voltage with a voltage on each of the plurality of wordlines WLs using the comparator. In addition, the leakage detection circuit 160 may output a signal indicating that leakage has occurred on a specific wordline among the plurality of wordlines WLs when the voltage on the specific wordline has a difference from the reference voltage that is greater than or equal to a threshold value. For example, the reference voltage may be understood to be the same as the program voltage applied through a wordline during program operation, but the voltages are not limited thereto.

Referring to FIGS. 6 to 8, the memory device 102B (e.g., the control logic circuit 130) may detect leakage between a selected wordline SWL and a string (for example, a first string ST1).

The control logic circuit 130 may apply an initial voltage VIC to each of the plurality of bitlines BL1 to BL4 using the plurality of page buffers PB1 to PB4.

For example, the control logic circuit 130 may apply the initial voltage VIC to each of the plurality of bitlines BL1 to BL4 while setting data for a program operation through the plurality of page buffers PB1 to PB4.

For example, the control logic circuit 130 may apply the initial voltage VIC to each of the plurality of bitlines BL1 to BL4 while storing data in at least a portion of the latches included in each of the plurality of page buffers PB1 to PB4.

For example, in some implementations, data is pre-programmed in memory cells connected to wordlines disposed below the selected wordline SWL (for example, in a negative Y-direction). For example, when the selected wordline SWL is the fourth wordline, in some implementations, data is pre-programmed in the memory cells connected to lines WL1 to WL3.

Accordingly, in some implementations, program operations on the memory device 102B of FIG. 7 are performed in a sequence starting from the first wordline WL1 to the nth wordline WLn. However, the order of the program operations on the memory device 102B is not limited thereto.

The control logic circuit 130 may apply the initial voltage VIC to the plurality of strings STs in a direction (for example, a positive Y-direction) from the ground select line GSL toward the string select lines SSL0 and SSL1 through the plurality of page buffers PB1 to PB4.

Referring to FIG. 8, the control logic circuit 130 may apply a high-level signal through the ground select line GSL to turn on transistors connected to the ground select line GSL.

Accordingly, the control logic circuit 130 may charge the initial voltage VIC to the memory cells connected to the first wordline WL1 and the selected wordline SWL in each of the plurality of strings STs.

For example, the operation of applying an initial voltage VIC to the plurality of strings STs may be understood to be substantially the same as the operation of applying the precharge voltage V_PC to the plurality of strings STs described in FIGS. 3 to 5.

In addition, the control logic circuit 130 may apply a first sense voltage VS1 to the selected wordline SWL. The first sense voltage VS1 may have a value greater than the initial voltage VIC. For example, the first sense voltage VS1 may have a value of 3V to 8V.

For example, the control logic circuit 130 may generate the first sense voltage VS1 using the voltage generator 150. In addition, the control logic circuit 130 may apply the first sense voltage VS1 to the selected wordline SWL through the row decoder 120.

Furthermore, the control logic circuit 130 may detect the voltage level V_SWL of the selected wordline SWL using the leakage detection circuit 160.

In some implementations, when the voltage level V_SWL of the selected wordline SWL is lower than the voltage level of the first sense voltage VS1, the control logic circuit 130 may determine that leakage between at least one of the plurality of strings STs and the selected wordline SWL has occurred.

For example, when the voltage level V_SWL of the selected wordline SWL is lower than the voltage level of the first sense voltage VS1, the control logic circuit 130 may determine that leakage has occurred from the selected wordline SWL to the first string ST1, as indicated by a dashed arrow in FIG. 7.

When it is determined that leakage between at least one of the plurality of strings STs and the selected wordline SWL has occurred, the control logic circuit 130 may output leakage information.

In some implementations, when the voltage level V_SWL of the selected wordline SWL is equal to the voltage level of the first sense voltage VS1, the control logic circuit 130 may determine that no leakage between the plurality of strings STs and the selected wordline SWL has occurred.

When it is determined that no leakage between the plurality of strings STs and the selected wordline SWL has occurred, the control logic circuit 130 may perform a program operation through the selected wordline SWL.

Referring to the above-described configurations, the control logic circuit 130 may apply the initial voltage VIC to the plurality of bitlines BL1 to BL4 using the plurality of page buffers PB1 to PB4 while setting data for a program operation.

For example, in some implementations, the control logic circuit 130 may apply the initial voltage VIC to the plurality of bitlines BL1 to BL4 using the plurality of page buffers PB1 to PB4 while storing data in at least one of the plurality of latches.

In addition, in some implementations, the control logic circuit 130 may apply a first sense voltage VS1 to the selected wordline SWL.

In addition, in some implementations, the control logic circuit 130 may determine whether leakage has occurred between the selected wordline SWL and the plurality of strings STs, based on a voltage level of the selected wordline SWL.

For example, in some implementations, the control logic circuit 130 may determine whether leakage has occurred between the wordline and the string before performing a program operation.

Thus, in some implementations, the memory device 102B may reduce the number of times program operations are performed through wordlines on which leakage has occurred. For example, the memory device 102B may improve the performance of program operations on the memory cell array 110 through the above-described configurations.

In addition, in some implementations, referring to the above-described configurations, the control logic circuit 130 may determine whether leakage has occurred on a wordline while setting data for a program operation.

As a result, in some implementations, the memory device 102B may significantly reduce an increase in time required for a program operation caused by an operation of detecting whether leakage has occurred.

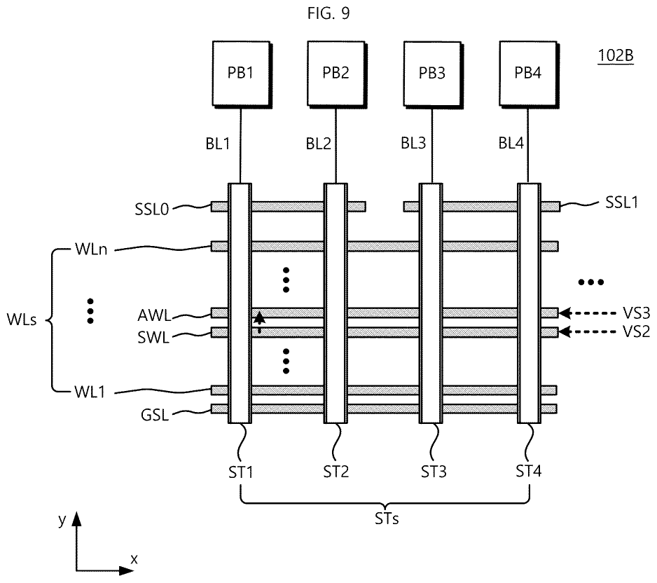

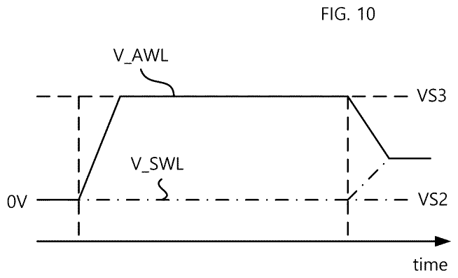

FIG. 9 is a diagram illustrating a configuration to detect leakage between wordlines by applying different voltages to a selected wordline and an adjacent wordline. FIG. 10 is a diagram illustrating voltage levels of a selected wordline and an adjacent wordline when leakage occurs between wordlines.

Referring to FIGS. 9 and 10, the memory device 102B (e.g., the control logic circuit 130) may detect leakage between a selected wordline SWL and an adjacent wordline AWL. The adjacent wordline AWL may be understood as a wordline adjacent to the selected wordline SWL among a plurality of wordlines WLs.

In some implementations, the control logic circuit 130 may apply a second sense voltage VS2 to the selected wordline SWL. Referring to FIG. 10, the second sense voltage VS2 may be 0 V. For example, the second sense voltage VS2 may be referred to as a ground voltage.

In addition, the control logic circuit 130 may apply a third sense voltage VS3 to the adjacent wordline AWL. Referring to FIG. 10, the third sense voltage VS3 may have a greater value than the second sense voltage VS2. For example, the third sense voltage VS3 may have a value of 8 volts.

For example, the control logic circuit 130 may generate the third sense voltage VS3 using the voltage generator 150. In addition, the control logic circuit 130 may apply the third sense voltage VS3 to the adjacent wordline AWL through the row decoder 120.

In addition, the control logic circuit 130 may detect a voltage level V_SWL of the selected wordline SWL using the leakage detection circuit 160.

In some implementations, when the voltage level V_SWL of the selected wordline SWL is higher than the voltage level of the second sense voltage VS2, the control logic circuit 130 may determine that leakage between the selected wordline SWL and the adjacent wordline AWL has occurred.

For example, when the voltage level V_SWL of the selected wordline SWL is higher than the voltage level of the second sense voltage VS2 and lower than the voltage level of the third sense voltage VS3, the control logic circuit 130 may determine that leakage has occurred from the adjacent wordline AWL to the selected wordline SWL.

In some implementations, the control logic circuit 130 may detect the voltage level V_AWL of the adjacent wordline AWL using the leakage detection circuit 160. The control logic circuit 130 may determine that leakage between the selected wordline SWL and the adjacent wordline AWL has occurred when the voltage level V_AWL on the adjacent wordline AWL is lower than a voltage level of the third detection voltage VS3.

In some implementations, when it is determined that leakage between the selected wordline SWL and the adjacent wordline AWL has occurred, the control logic circuit 130 may output leakage information.

In some implementations, when the voltage level V_SWL of the selected wordline SWL is equal to the voltage level of the second sense voltage VS2, the control logic circuit 130 may determine that no leakage has occurred in the selected wordline SWL.

When it is determined that no leakage between the selected wordline SWL and the adjacent wordline AWL has occurred, the control logic circuit 130 may perform a program operation through the selected wordline SWL.

Referring to the above-described configurations, in some implementations, the control logic circuit 130 may apply different voltages to the selected wordline SWL and the adjacent wordline AWL while setting data for a program operation. In addition, the control logic circuit 130 may determine whether leakage has occurred between the selected wordline SWL and the adjacent wordline AWL, based on the voltage level on the selected wordline SWL.

For example, in some implementations, the control logic circuit 130 may determine whether leakage has occurred between wordlines, before performing a program operation.

Thus, in some implementations, the memory device 102B may reduce the number of times program operations are performed over wordlines where leaks occur. With the above-described configurations, the memory device 102B may improve the performance of program operations on the memory cell array 110.

In addition, in some implementations, referring to the above-described configurations, the control logic circuit 130 may determine whether leakage has occurred in a wordline while setting data for a program operation.

As a result, in some implementations, the memory device 102B according may significantly reduce an increase in time required for a program operation caused by an operation of detecting whether leakage has occurred.

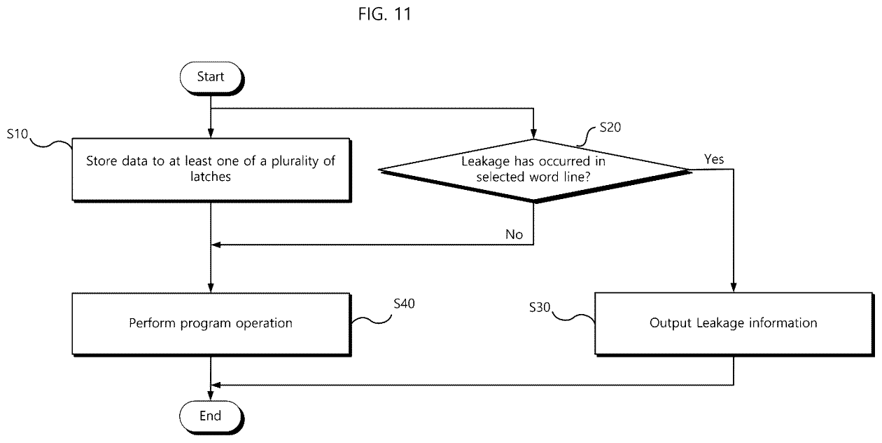

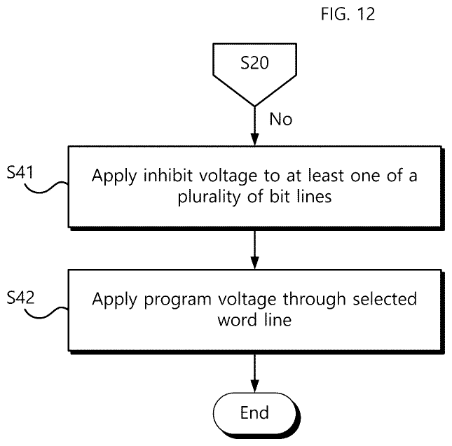

FIG. 11 is a flowchart illustrating an example of a method of operating a memory device. FIG. 12 is a flowchart illustrating an example of a method of performing a program operation when it is determined that no leakage is detected in a memory device.

Referring to FIG. 11, the memory device 102 (e.g., the control logic circuit 130) may perform a program operation on whether leakage has occurred in a selected wordline SWL.

For example, the control logic circuit 130 may output leakage information when it is determined that leakage has occurred in the selected wordline SWL.

Alternatively, the control logic circuit 130 may perform a program action when it is determined that no leakage has occurred in the selected wordline SWL.

In operation S10, the control logic circuit 130 may store data in (or to) at least one of the plurality of latches.

For example, the control logic circuit 130 may store data for a program operation in at least one of the latches respectively included in each of the plurality of page buffers PB1 to PBn.

For example, the control logic circuit 130 may store inhibit data IND in the first latch LT1 included in the first page buffer PB1.

For example, the control logic circuit 130 may copy data stored in at least a portion of the plurality of latches and store the copied data in other latches.

For example, in operation S10, an operation in which the control logic circuit 130 stores data in at least one of the plurality of latches may be understood as an operation of setting data to perform a program operation.

In operation S20, the control logic circuit 130 may determine whether leakage has occurred in the selected wordline SWL.

For example, the control logic circuit 130 may determine whether leakage occurs in the selected wordline SWL, among the plurality of wordlines WLs, while storing data in at least one of the plurality of latches.

For example, the control logic circuit 130 may detect whether leakage between the strings connected to each of the plurality of bitlines BLs and the selected wordlines SWLs has occurred while setting data to perform a program operation.

For example, the control logic circuit 130 may detect whether leakage has occurred between a selected wordline SWL and an adjacent wordline AWL has occurred while setting data to perform a program operation.

For example, the control logic circuit 130 may determine whether leakage has occurred in the selected wordline SWL before performing a program operation on the at least one memory cell.

Referring to the above-described configurations, at least a portion of operations S10 and S20 may be performed simultaneously.

Thus, the memory device 102 may significantly reduce an increase in time required for a program operations caused by an operation of detecting whether leakage has occurred.

In operation S30, the control logic circuit 130 may output leakage information.

For example, the control logic circuit 130 may output leakage information when it is determined that leakage has occurred in the selected wordline SWL.

For example, the leakage information may include information on (e.g., indicating or identifying) the selected word line SWL and/or the first string ST1 where the leakage occurs, and/or the adjacent wordline AWL.

In operation S40, the control logic circuit 130 may perform a program operation.

For example, the control logic circuit 130 may perform program operations on memory cells connected to the selected wordline SWL when it is determined that no leakage has occurred in the selected wordline SWL.

Referring to FIGS. 11 and 12, the control logic circuit 130 may program data in at least a portion of the memory cells connected to the selected wordline SWL.

In operation S41, the control logic circuit 130 may apply an inhibit voltage to at least one of the plurality of bitlines BLs.

For example, the control logic circuit 130 may apply an inhibit voltage to at least one bitline connected to a page buffer in which the inhibit data is stored, among the plurality of page buffers PB1 to PBn.

For example, the control logic circuit 130 may apply an inhibit voltage to the at least one bitline connected to the page buffer in which the inhibit data is stored, through operation S10 of FIG. 11.

In operation S42, the control logic circuit 130 may apply a program voltage through the selected wordline SWL.

For example, the control logic circuit 130 may apply a program voltage through the selected wordline SWL in response to applying an inhibit voltage through the at least one bitline.

Data may be programmed in memory cells connected to a bitline to which the inhibit voltage is not applied, among the memory cells connected to the selected wordline SWL.

Referring to the above-described configurations, the control logic circuit 130 may determine whether leakage has occurred in the selected wordline SWL before performing a program operation.

As a result, the memory device 102 may reduce the number of times program operations are performed through wordlines in which leakage has occurred.

For example, in some implementations, with the above-described configurations, the memory device 102 may improve the performance of program operations.

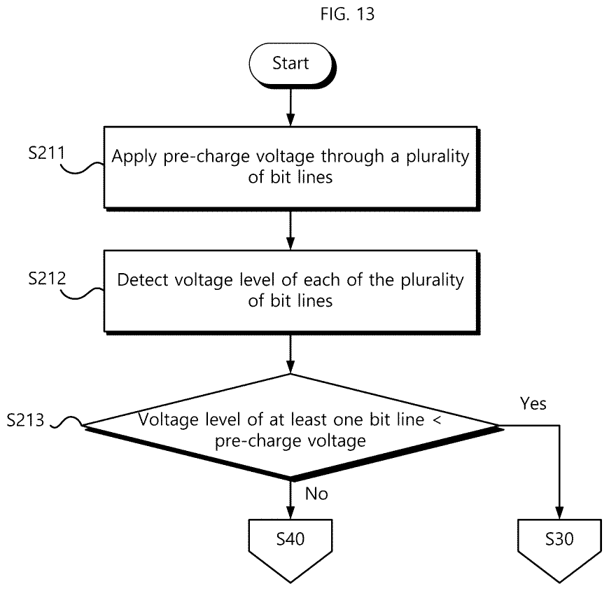

FIG. 13 is a flowchart illustrating an example of a method of detecting leakage between a first string and a selected wordline using a page buffer.

Referring to FIG. 13, the memory device 102 may detect leakage between a string (a channel) and a wordline using a plurality of page buffers PB1 to PB4.

For example, the control logic circuit 130 may apply a precharge voltage V_PC to a plurality of strings STs using the plurality of page buffers PB1 to PB4 to detect leakage between the plurality of strings STs and a selected wordline SWL.

In operation S211, the control logic circuit 130 may apply the precharge voltage V_PC to a plurality of bitlines BLs.

For example, the control logic circuit 130 may apply the precharge voltage V_PC to the plurality of strings STs through the plurality of bitlines BLs using the plurality of page buffers PB1 through PB4.

Memory cells connected to the selected wordlines SWL in each of the plurality of strings STs may be charged with the precharge voltage V_PC.

In operation S212, the control logic circuit 130 may detect a voltage level of each of the plurality of bitlines BLs.

For example, the control logic circuit 130 may detect a voltage level of each of the plurality of bitlines BLs using the plurality of page buffers PB1 to PBn.

For example, the control logic circuit 130 may detect a voltage level V_BL1 on the first bitline BL1 using the first page buffer PB1 (or the first latch LT1).

In operation S213, the control logic circuit 130 may determine whether the voltage level V_BL1 on the first bitline BL1 is lower than a voltage level of the precharge voltage V_PC.

In some implementations, when the voltage level V_BL1 on the first bitline BL1 is lower than the voltage level of the precharge voltage V_PC, the control logic circuit 130 may determine that leakage between the first string ST1 and the selected wordline SWL has occurred.

For example, when the voltage level V_BL1 of the first bitline BL1 is lower than the voltage level V_PC of the precharge voltage V_PC, the control logic circuit 130 may determine that leakage has occurred from the first string ST1 to the selected wordline SWL.

When it is determined that leakage between the first string ST1 and the selected wordline SWL has occurred, the control logic circuit 130 may output leakage information. The operation of outputting the leakage information may be understood to be substantially the same as operation S30 of FIG. 11. For example, the control logic circuit 130 may output information identifying the first string ST1 and/or the selected wordline SWL.

In some implementations, when the voltage level V_BL1 of the first bitline BL1 is equal to the voltage level of the precharge voltage V_PC, the control logic circuit 130 may determine that no leakage has occurred between the first string ST1 and the selected wordline SWL.

When it is determined that no leakage has occurred between the plurality of strings STs and the selected wordline SWL, the control logic circuit 130 may perform a program operation through the selected wordline SWL. The operation of performing the program operation may be understood to be substantially the same as operation S40 of FIG. 11.

Referring to the above-described configurations, the control logic circuit 130 may determine whether leakage has occurred on the selected wordline SWL before performing a program operation.

Thus, the memory device 102 may reduce the number of times program operations are performed through wordlines in which leakage has occurred. For example, with the above-described configurations, the memory device 102 may improve the performance of program operations on the memory cell array 110.

In some implementations, at least a portion of operation S211 to operation S213 may be performed concurrently with operation S10 of FIG. 11.

For example, the control logic circuit 130 may determine whether leakage has occurred in the selected wordline SWL while setting data for a program operation.

As a result, the memory device 102 may significantly reduce an increase in time required for a program operation caused by an operation of detecting whether leakage has occurred.

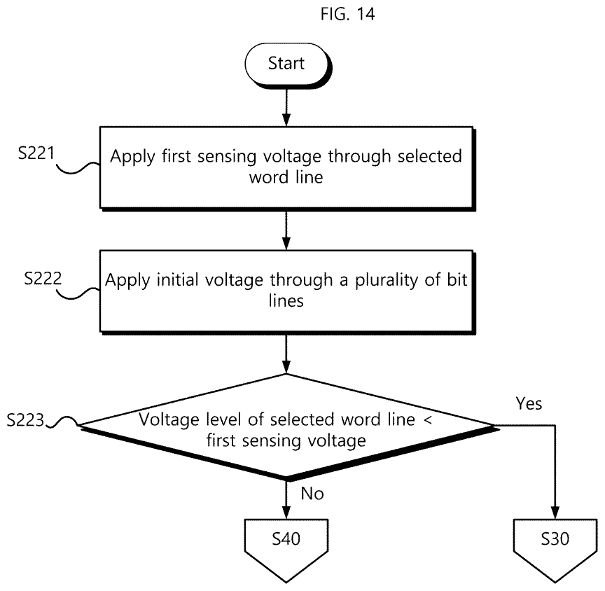

FIG. 14 is a flowchart illustrating an example of a method of detecting leakage between a first string and a selected wordline by applying a voltage to the selected wordline.

Referring to FIG. 14, the memory device 102 (e.g., the control logic circuit 130) may detect leakage between a selected wordline SWL and a string (for example, a first string ST1).

In operation S221, the control logic circuit 130 may apply a first sense voltage VS1 to the selected wordline SWL.

For example, the control logic circuit 130 may generate the first sense voltage VS1 using the voltage generator 150. In addition, the control logic circuit 130 may apply the first sense voltage VS1 to the selected wordline SWL through the row decoder 120.

In operation S222, the control logic circuit 130 may apply an initial voltage VIC to each of the plurality of bitlines BL1 through BL4. The initial voltage VIC may have a value less than the first sense voltage VS1.

For example, the control logic circuit 130 may apply the initial voltage VIC to each of the plurality of bitlines BLs while setting data for a program operation through the plurality of page buffers PB1 to PBn.

For example, the control logic circuit 130 may apply the initial voltage VIC to each of the plurality of bitlines BLs while storing inhibit data in at least a portion of the latches included in each of the plurality of page buffers PB1 to PBn.

Accordingly, memory cells connected to the selected wordline SWL in each of the plurality of strings STs may be charged with the initial voltage VIC.

However, the order in which operation S221 and S222 are performed is not limited to the above-described example. In some implementations, the order may be reversed, or at least a portion of operations S221 and S222 may be performed simultaneously.

In operation S223, the control logic circuit 130 may determine whether a voltage level V_SWL of the selected wordline SWL is lower than a voltage level of the first sense voltage VS1.

For example, the control logic circuit 130 may detect a voltage level V_SWL of the selected wordline SWL using the leakage detection circuit 160. In addition, the control logic circuit 130 may determine whether the voltage level V_SWL of the detected selected wordline SWL is lower than the voltage level of the first sense voltage VS1.

In some implementations, when the voltage level V_SWL of the selected wordline SWL is lower than the voltage level of the first sense voltage VS1, the control logic circuit 130 may determine that leakage has occurred between at least a portion of the plurality of strings STs and the selected wordline SWL.

For example, when the voltage level V_SWL of the selected wordline SWL is lower than the voltage level of the first sense voltage VS1, the control logic circuit 130 may determine that leakage has occurred from the selected wordline SWL to the first string ST1.

When it is determined that leakage has occurred between at least one of the plurality of strings STs and the selected wordline SWL, the control logic circuit 130 may output leakage information. The operation of outputting the leakage information may be understood to be substantially the same as operation S30 of FIG. 11. For example, the control logic circuit 130 may output information indicating the selected wordline and/or the first string ST1.

In some implementations, when the voltage level V_SWL of the selected wordline SWL is equal to the voltage level of the first sense voltage VS1, the control logic circuit 130 may determine that no leakage has occurred between the plurality of strings STs and the selected wordline SWL.

When it is determined that no leakage has occurred between the plurality of strings STs and the selected wordline SWL, the control logic circuit 130 may perform a program operation through the selected wordline SWL. The operation of performing the program operation may be understood to be substantially the same as operation S40 of FIG. 11.

Referring to the above-described configurations, in some implementations, the control logic circuit 130 may apply the initial voltage VIC to a plurality of bitlines BLs using a plurality of page buffers PB1 to PBn while setting data for a program operation.

For example, the control logic circuit 130 may apply the initial voltage VIC to the plurality of bitlines BLs using the plurality of page buffers PB1 to PBn while storing the inhibit data IND in at least one of the plurality of latches.

In addition, the control logic circuit 130 may apply a first sense voltage VS1 to the selected wordline SWL.

Furthermore, the control logic circuit 130 may determine whether leakage has occurred between the selected wordline SWL and the plurality of strings STs, based on a voltage level of the selected wordline SWL.

For example, the control logic circuit 130 may determine whether leakage has occurred between the wordline and the string before performing a program operation.

Thus, in some implementations, the memory device 102 may reduce the number of times program operations are performed through wordlines on which leakage has occurred. For example, with the above-described configurations, the memory device 102 may improve the performance of a program operation on the memory cell array 110.

In some implementations, at least a portion of operation S221 to operation S223 may be performed concurrently with operation S10 of FIG. 11.

For example, referring to the above-described configurations, the control logic circuit 130 may determine whether leakage has occurred in a wordline while setting data for a program operation.

As a result, the memory device 102 may significantly reduce an increase in time required for program operations caused by an operation of detecting whether leakage has occurred.

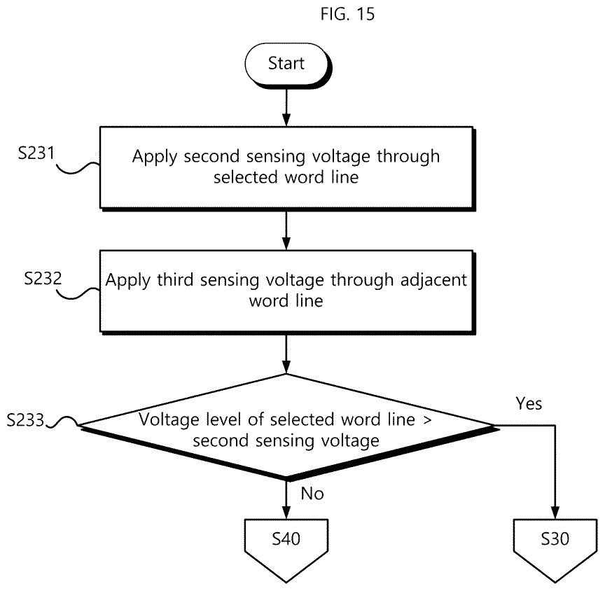

FIG. 15 is a flowchart illustrating an example of a method of detecting leakage between wordlines by applying different voltages to a selected wordline and an adjacent wordline.

Referring to FIG. 15, the memory device 102 (e.g., the control logic circuit 130) may detect leakage between a selected wordline SWL and an adjacent wordline AWL. The adjacent wordline AWL may be understood as a wordline adjacent to the selected wordline SWL, among a plurality of wordlines WLs.

In operation S231, the control logic circuit 130 may apply a second sense voltage VS2 to the selected wordline SWL. For example, the second sense voltage VS2 may be 0 V. For example, the second sense voltage VS2 may be referred to as a ground voltage.

In operation S232, the control logic circuit 130 may apply a third sense voltage VS3 to the adjacent wordline AWL. For example, the third sense voltage VS3 may have a greater value than the second sense voltage VS2.

In operation S233, the control logic circuit 130 may determine whether a voltage level V_SWL of the selected wordline SWL is higher than a voltage level of the second sense voltage VS2.

For example, the control logic circuit 130 may detect a voltage level V_SWL of the selected wordline SWL using the leakage detection circuit 160. In addition, the control logic circuit 130 may determine whether the voltage level V_SWL of the detected selected wordline SWL is higher than the voltage level of the second sense voltage VS2.

In some implementations, when the voltage level V_SWL of the selected wordline SWL is higher than the voltage level of the second sense voltage VS2, the control logic circuit 130 may determine that leakage has occurred between the selected wordline SWL and the adjacent wordline AWL.

For example, when the voltage level V_SWL of the selected wordline SWL is higher than the voltage level of the second sense voltage VS2, the control logic circuit 130 may determine that leakage has occurred from the neighboring wordline AWL to the selected wordline SWL.

In some implementations, the control logic circuit 130 may detect the voltage level V_AWL of the adjacent wordline AWL using the leakage detection circuit 160. In addition, the control logic circuit 130 may determine that leakage has occurred between the selected wordline SWL and the adjacent wordline AWL when the voltage level V_AWL of the adjacent wordline AWL is lower than the third detection voltage VS3.

In some implementations, when it is determined that leakage has occurred between the selected wordline SWL and the adjacent wordline AWL, the control logic circuit 130 may output leakage information. The operation of outputting the leakage information may be understood to be substantially the same as operation S30 of FIG. 11. For example, the control logic circuit 130 may output information indicating at least one of the selected wordline SWL or the adjacent wordline AWL.

In some implementations, when the voltage level V_SWL of the selected wordline SWL is equal to the voltage level of the second sense voltage VS2, the control logic circuit 130 may determine that no leakage has occurred between the selected wordline SWL and the adjacent wordline AWL.

When it is determined that no leakage has occurred between the selected wordline SWL and the adjacent wordline AWL, the control logic circuit 130 may perform a program operation through the selected wordline SWL. The operation of performing the program operation may be understood to be substantially the same as operation S40 of FIG. 11.

In some implementations, at least a portion of operation S231 to operation S233 may be performed concurrently with operation S10 of FIG. 11.

Referring to the above-described configurations, in some implementations, the control logic circuit 130 may apply different voltages to the selected wordline SWL and the adjacent wordline AWL while setting data for a program operation. In addition, the control logic circuit 130 may determine whether leakage has occurred between the selected wordline SWL and the adjacent wordline AWL, based on the voltage level on the selected wordline SWL.

For example, the control logic circuit 130 may determine whether leakage has occurred between wordlines before performing a program operation.

Thus, in some implementations, the memory device 102 may reduce the number of times program operations are performed vias wordlines. For example, with the above-described configurations, the memory device 102 may improve the performance of program operations on the memory cell array 110.

In addition, referring to the above-described configurations, in some implementations, the control logic circuit 130 may determine whether leakage has occurred in the selected wordline SWL while setting data for a program operation.

As a result, the memory device 102B may significantly reduce an increase in time required for program operations caused by an operation of detect whether leakage has occurred.

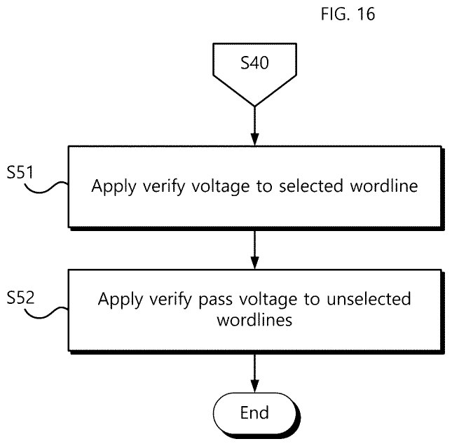

FIG. 16 is a flowchart illustrating an example of a method of performing a verify operation after a program operation of a memory device.

Referring to FIG. 16, the memory device 102 (e.g., the control logic circuit 130) may perform a program operation on a specific memory cell and then perform a verify operation on the specific memory cell.

In operation S51, the control logic circuit 130 may apply a verify voltage to a selected wordline SWL.

For example, the control logic circuit 130 may generate the verify voltage using the voltage generator 150. In addition, the control logic circuit 130 may apply the verify voltage to the selected wordline SWL through the row decoder 120.

In operation S52, the control logic circuit 130 may apply a verify pass voltage to unselected wordlines, other than the selected wordlines SWL, among the plurality of wordlines WLs.

For example, the control logic circuit 130 may generate the verify pass voltage using the voltage generator 150. In addition, the control logic circuit 130 may apply the verify voltage to an unselected wordline through the row decoder 120.

However, the order in which operation S51 and operations S52 are performed is not limited to that illustrated in FIG. 16. In some implementations, at least a portion of operations S51 and S52 may be performed simultaneously, or the order may be reversed.

Furthermore, the control logic circuit 130 may determine whether current flows in the memory cell connected to the selected wordline SWL, using a plurality of page buffers PB1 to PBn.

For example, the control logic circuit 130 may determine that the program is complete in a memory cell connected to the selected wordline SWL when no current flows in the memory cell connected to the selected wordline SWL.

For example, the control logic circuit 130 may determine that the program is not complete in a memory cell connected to the selected wordline SWL when current flows in the memory cell connected to the selected wordline SWL.

It will be understood that the verify operation performed by the control logic circuit 130 on the memory cell is substantially the same as a read operation on the memory cell.

For example, referring to the above-described configurations, in some implementations, the control logic circuit 130 may perform a verify operation on the memory cell connected to the wordline SWL after performing a program operation because it is determined that no leakage has occurred in the selected wordline SWL.

As a result, in some implementations, the memory device 102 may improve the performance of program operations.

As described above, the control logic circuit 130 may determine whether leakage has occurred in the selected wordline SWL while setting data for a program operation.

For example, the control logic circuit 130 may determine whether leakage occurs between the plurality of strings STs and the selected wordline SWL while storing the inhibit data IND in at least one of the plurality of latches.

For example, the control logic circuit 130 may determine leakage occurs between adjacent wordlines while storing data in at least one of the plurality of latches.

For example, the control logic circuit 130 may determine whether leakage has occurred on the selected wordline SWL before performing a program operation.

Thus, in some implementations, the memory device 102 may reduce the number of times program operations are performed through wordlines in which leakage has occurred. For example, with the above-described configurations, the memory device 102 may improve the performance of program operations on the memory cell array 110.

In addition, referring to the above-described configurations, the control logic circuit 130 may determine whether leakage has occurred in the selected wordline SWL while setting data for a program operation.

As a result, the memory device 102 may significantly reduce an increase in time required for program operations caused by an operation of detecting whether leakage has occurred.

As set forth above, in some implementations of the present disclosure, a memory device may detect leakage before performing a program operation. As a result, the memory device may improve the performance of program operations.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to various examples, it will be apparent to those of ordinary skill in the art that various changes and modifications may be made thereto without departing from the spirit and scope of the present disclosure as set forth in the following claims.

What is claimed is:

1. A method of operation of a memory device,
wherein the memory device comprises a plurality of memory cells, wherein each memory cell of the plurality of memory cells is connected to a corresponding bitline of a plurality of bitlines and a corresponding wordline of a plurality of wordlines,
wherein the memory device comprises a plurality of page buffers, each page buffer of the plurality of page buffers comprising a respective latch of a plurality of latches and connected to a respective bitline of the plurality of bitlines, and
wherein the method comprises:
storing data for performing a program operation in at least one latch of the plurality of latches; and
detecting, while storing the data in the at least one latch of the plurality of latches, whether leakage has occurred in a selected wordline of the plurality of wordlines; and
based on determining that the leakage has occurred, outputting leakage information, or
based on determining that the leakage has not occurred, performing the program operation through the selected wordline.

2. The method of claim 1, comprising, based on determining that the leakage has occurred, outputting the leakage information,
wherein the leakage information comprises an indicator of the selected wordline.

3. The method of claim 1, comprising, based on determining that the leakage has not occurred, performing the program operation through the selected wordline, wherein:
the data comprises inhibit data, and
performing the program operation through the selected wordline comprises:
applying an inhibit voltage to at least one bitline connected to at least one page buffer comprising the at least one latch in which the inhibit data is stored; and
applying a program voltage through the selected wordline.

4. The method of claim 1, wherein detecting whether the leakage has occurred in the selected wordline comprises:
applying a precharge voltage through the plurality of bitlines;
detecting a voltage level of each of the plurality of bitlines using the plurality of page buffers; and
determining that leakage has occurred between a first string connected to a first bitline, of the plurality of bitlines, and the selected wordline based on a voltage level of the first bitline being lower than the precharge voltage.

5. The method of claim 1, wherein detecting whether the leakage has occurred in the selected wordline comprises:
applying a precharge voltage through the plurality of bitlines;
detecting a voltage level of each of the plurality of bitlines using the plurality of page buffers; and
determining that leakage has not occurred between a plurality of strings, each connected to a respective one of the plurality of bitlines, and the selected wordline based on the voltage level of each of the plurality of bitlines being equal to the precharge voltage.

6. The method of claim 1, wherein detecting whether the leakage has occurred in the selected wordline comprises:
applying a first sensing voltage through the selected wordline;
applying an initial voltage, smaller than the first sensing voltage, through the plurality of bitlines;
detecting a voltage level of the selected wordline using a leakage detection circuit connected to the selected wordline; and
determining whether the leakage has occurred in the selected wordline based on the voltage level of the selected wordline.

7. The method of claim 6, wherein determining whether the leakage has occurred in the selected wordline comprises determining that the leakage has occurred in the selected wordline based on the voltage level of the selected wordline being lower than the first sensing voltage.

8. The method of claim 1, wherein detecting whether the leakage has occurred in the selected wordline comprises:
applying a second sensing voltage through the selected wordline;
applying a third sensing voltage, greater than the second sensing voltage, through an adjacent wordline adjacent to the selected wordline;
detecting a voltage level of the selected wordline using a leakage detection circuit connected to the selected wordline; and
determining that the leakage has occurred in the selected wordline based on the voltage level of the selected wordline being higher than the second sensing voltage.

9. The method of claim 8, wherein detecting whether the leakage has occurred in the selected wordline comprises:
determining that the leakage has occurred from the adjacent wordline to the selected wordline based on a voltage level of the adjacent wordline being lower than the third sensing voltage.

10. The method of claim 1, comprising:
performing a verify operation on memory cells connected to the selected wordline in response to the program operation being performed through the selected wordline, wherein performing the verify operation comprises:
applying a verify voltage through the selected wordline; and
applying a verify pass voltage through unselected wordlines, other than the selected wordline, of the plurality of wordlines.

11. A method of operation of a memory device
wherein the memory device comprises a plurality of memory cells, wherein each memory cell of the plurality of memory cells is connected to a corresponding bitline of a plurality of bitlines and a corresponding wordline of a plurality of wordlines,
wherein the memory device comprises a plurality of page buffers, each page buffer of the plurality of page buffers comprising a respective latch of a plurality of latches and connected to a respective bitline of the plurality of bitlines, and
wherein the method comprises:
storing inhibit data in at least one latch of the plurality of latches;
while storing the inhibit data in the at least one latch, determining whether leakage has occurred in a selected wordline of the plurality of wordlines; and
outputting leakage information based on determining that the leakage has occurred in the selected wordline, or
performing a program operation through the selected wordline based on determining that the leakage has not occurred in the selected wordline.

12. The method of claim 11, comprising performing the program operation through the selected wordline, wherein performing the program operation through the selected wordline comprises:
applying an inhibit voltage through at least one bitline connected to at least one page buffer comprising the at least one latch in which the inhibit data is stored; and
applying a program voltage through the selected wordline.

13. The method of claim 11, wherein determining whether the leakage has occurred in the selected wordline comprises:
applying a precharge voltage through the plurality of bitlines;
sensing a voltage level of each bitline of the plurality of bitlines through the plurality of page buffers; and
determining that leakage has occurred between a first string connected to a first bitline, of the plurality of bitlines, and the selected wordline based on a voltage level of the first bitline being lower than the precharge voltage.

14. The method of claim 11, wherein determining whether leakage has occurred in the selected wordline comprises:
applying an initial voltage to a plurality of strings through the plurality of bitlines;
applying a first sensing voltage, greater than the initial voltage, through the selected wordline;
detecting a voltage level of the selected wordline using a leakage detection circuit connected to the selected wordline; and
determining that the leakage has occurred in the selected wordline based on the voltage level of the selected wordline being lower than the first sensing voltage.

15. The method of claim 11, wherein determining whether leakage has occurred in the selected wordline comprises:
applying a second sensing voltage through the selected wordline;
applying a third sensing voltage, greater than the second sensing voltage, through an adjacent wordline adjacent to the selected wordline;
detecting a voltage level of the selected wordline using a leakage detection circuit connected to the selected wordline; and
determining that leakage has occurred in the selected wordline based on the voltage level of the selected wordline being higher than the second sensing voltage.

16. A memory device comprising:
a memory cell array comprising a plurality of memory cells connected to a plurality of wordlines and a plurality of bitlines;
a page buffer circuit comprising a plurality of page buffers, each page buffer of the plurality of page buffers connected to a respective bitline of the plurality of bitlines; and
a control logic circuit connected to the memory cell array and the page buffer circuit,
wherein the control logic circuit is configured to:
store inhibit data in at least one page buffer of the plurality of page buffers,
while storing the inhibit data in the at least one page buffer, detect whether leakage has occurred in a selected wordline of the plurality of wordlines, and
output leakage information based on determining that the leakage has occurred in the selected wordline.

17. The memory device of claim 16, wherein the control logic circuit is configured to, based on determining that the leakage has not occurred in the selected wordline:
apply an inhibit voltage through at least one bitline, of the plurality of bitlines, connected to the at least one page buffer in which the inhibit data is stored; and
apply a program voltage through the selected wordline.

18. The memory device of claim 16, wherein the control logic circuit is configured to, while storing the inhibit data in the at least one page buffer:
apply a precharge voltage through the plurality of bitlines;
detect a voltage level of each bitline of the plurality of bitlines through the plurality of page buffers; and
determine that leakage has occurred between a first string connected to a first bitline, of the plurality of bitlines, and the selected wordline based on a voltage level of the first bitline being lower than the precharge voltage.

19. The memory device of claim 16, comprising a leakage detection circuit connected between the plurality of wordlines and the control logic circuit,
wherein the control logic circuit is configured to, while storing the inhibit data in the at least one page buffer:
apply a first sensing voltage through the selected wordline;
apply an initial voltage, smaller than the first sensing voltage, through the plurality of bitlines;
detect a voltage level of the selected wordline using the leakage detection circuit; and
determine whether the leakage has occurred in the selected wordline based on the voltage level of the selected wordline.

20. The memory device of claim 16, comprising a leakage detection circuit connected between the plurality of wordlines and the control logic circuit,
wherein the control logic circuit is configured to, while storing the inhibit data in the at least one page buffer:
apply a second sensing voltage through the selected wordline;
apply a third sensing voltage, greater than the second sensing voltage, through an adjacent wordline adjacent to the selected wordline;
detect a voltage level of the selected wordline using the leakage detection circuit; and
determine whether the leakage has occurred in the selected wordline based on the voltage level of the selected wordline.
